(19) United States
(12) Patent Application Publication
(10) Pub. No.: US 2025/0286029 A1
(43) Pub. Date: Sep. 11, 2025

(54) SEMICONDUCTOR DEVICE

(71) Applicant: SUZHOU NOVOSENSE MICROELECTRONICS CO., LTD., Suzhou (CN)

(72) Inventor: Yuping GONG, Suzhou (CN)

(73) Assignee: SUZHOU NOVOSENSE MICROELECTRONICS CO., LTD., Suzhou (CN)

(21) Appl. No.: 18/950,080

(22) Filed: Nov. 16, 2024

(30) Foreign Application Priority Data
Mar. 8, 2024 (CN) 202410269272.5

(51) Int. Cl. H01L 25/16; H01L 23/00; H01L 23/057; H01L 23/495

(52) U.S. Cl. CPC H01L 25/16; H01L 23/057; H01L 23/49548; H01L 24/14; H01L 24/48; H10D 1/47; H01L 2224/08245; H01L 2224/14131; H01L 2924/1207

(57) ABSTRACT

The present invention discloses a semiconductor device, the semiconductor device comprises a semiconductor chip and a shunt resistor structure, the semiconductor chip comprises a plurality of conductive terminals, the shunt resistor structure comprises a main part and a connecting part, the connecting part is connected to the end of the main part to form an accommodating space, where the semiconductor chip is located in. The technical solution provided by this application can reduce the occupied area of the semiconductor device.

### CROSS-REFERENCE TO RELATED APPLICATIONS

This application claims the benefit of China Patent Application No. 202410269272.5, filed with the China National Intellectual Property Administration on Mar. 8, 2024 and entitled “SEMICONDUCTOR DEVICE ”, the disclosures of which are incorporated by reference herein in their entirety.

### TECHNICAL FIELD

This application relates to the technical field of semiconductor, and particularly to a semiconductor device.

### BACKGROUND

With the development of technology, the demand for semiconductor devices is also increasing, especially for semiconductor devices that use chips. How to reduce the area of semiconductor devices is a difficult problem.

The existing semiconductor devices usually require a chip and a shunt resistor, which are parallel and tiled. Therefore, on the basis of increasing requirements for semiconductor devices, how to reduce the area of semiconductor devices is an urgent problem to be solved.

### SUMMARY

This application provides a semiconductor device that can reduce the occupied area of the semiconductor device.

According to the first aspect of the application, the application provides a semiconductor device, comprising a semiconductor chip, the semiconductor chip comprises a plurality of conductive terminals; the semiconductor device further comprises a shunt resistor structure, the shunt resistor structure comprises a main part and a connecting part, the connecting part is connected to the end of the main part to form an accommodating space, the semiconductor chip is located in the accommodating space.

Furthermore, the semiconductor chip is connected to the main part, the plurality of conductive terminals of the semiconductor chip comprise a plurality of solder balls; the plurality of solder balls are arranged on one side of the semiconductor chip away from the main part.

Furthermore, one end of the plurality of solder balls that is being away from the main part aligns with one end of the connecting part being away from the main part.

Furthermore, the semiconductor device further comprises a first plastic package, the first plastic package partially covers the shunt resistor structure and the semiconductor chip; wherein, the first plastic package is exposed at one end of the plurality of solder balls away from the main part.

Furthermore, the first plastic package is exposed at one side of the main part away from the semiconductor chip.

Furthermore, the first plastic package isn't exposed at one side of the main part away from the semiconductor chip.

Furthermore, a lead frame, the lead frame has a first surface and a plurality of lead terminals, the first surface is configured to connect and carry the semiconductor chip and the shunt resistor structure; wherein, each conductive terminal of the semiconductor chip is electrically connected to the corresponding lead terminal, the connecting part of the shunt resistor structure is electrically connected to the corresponding lead terminal.

Furthermore, the plurality of conductive terminals comprise a plurality of solder balls, the plurality of solder balls are arranged on one side of the semiconductor chip away from the main part.

Furthermore, the plurality of conductive terminals comprise a plurality of solder pads, the plurality of solder pads are arranged on one side of the semiconductor chip away from the main part.

Furthermore, the semiconductor device further comprises a wire bonding which electrically connects the semiconductor chip to the corresponding lead terminal.

Furthermore, the semiconductor device further comprises: a second plastic package, the second plastic package partially covers the lead frame, the semiconductor chip, and the shunt resistor structure.

Furthermore, the second plastic package is exposed at one side of the lead frame away from the semiconductor chip.

Furthermore, the second plastic package is exposed at one side of the main part away from the semiconductor chip.

Furthermore, the second plastic package isn't exposed at one side of the main part away from the semiconductor chip.

Furthermore, the semiconductor chip comprises a CSP chip.

Through one or more of the above embodiments in this application, the following technical effects can be achieved at least:

In the disclosed technical solution of the application, by adjusting the positional relationship between the semiconductor chip and the shunt resistor structure, the semiconductor chip and the shunt resistor structure are no longer parallel and tiled, thereby reducing the occupied area of the semiconductor device.

### BRIEF DESCRIPTION OF THE DRAWINGS

The technical solution and other beneficial effects of the application will become apparent through a detailed description of specific embodiments with reference to the accompanying drawings.

FIG. 1 is a schematic diagram of the structure of a semiconductor device provided in embodiment one of the application;

FIG. 2 is a schematic diagram of the packaged structure of a semiconductor device provided in embodiment one of the application;

FIG. 3 is a schematic diagram of the structure of a semiconductor device provided in embodiment two of the application;

FIG. 4 is an exploded view of the lead frame of FIG. 3 after decomposing treatment;

FIG. 5 is a schematic diagram of the packaged structure of a semiconductor device provided in embodiment two of the application;

FIG. 6 is a schematic diagram of the structure of a semiconductor device provided in embodiment three of the application;

FIG. 7 is an exploded view of the shunt resistor structure of FIG. 6 after decomposing treatment;

FIG. 8 is a schematic diagram of the packaged structure of a semiconductor device provided in embodiment three of the application.

### FIGURE MARKINGS

1—semiconductor chip; 2—shunt resistor structure; 21—main part; 22—connecting part; 23—accommodating space; 3—first plastic package; 11—conductive terminal; 4—lead frame; 41—first surface; 5—second plastic package; 6—adhesive layer.

### DETAILED WAYS

The following will provide a clear and complete description of the technical solution in the embodiments of the present application combined with the accompanying drawings. Obviously, the described embodiments are only part of the embodiments of the present application, not all of them. Based on the embodiments in the present application, all other embodiments obtained by those skilled in the art without creative labor fall within the scope of protection of the present application.

In the description of the present application, it should be noted that unless otherwise expressly specified and limited, the term “and/or” used herein is merely a description of the associative relationship between objects, indicating the possibility of three relationships. For example, “A and/or B” can indicate: the separate existence of A, the simultaneous existence of A and B, or the separate existence of B. In addition, the character “/” in this article, unless otherwise specified, generally represents an “or” relationship between the associated objects before and after it.

The existing semiconductor devices usually require a chip and a shunt resistor, which are parallel and tiled. Therefore, on the basis of increasing requirements for semiconductor devices, how to reduce the area of semiconductor devices is an urgent problem to be solved.

The embodiment of the present application provides a semiconductor device that can reduce the occupied area of the semiconductor device.

### Embodiment One

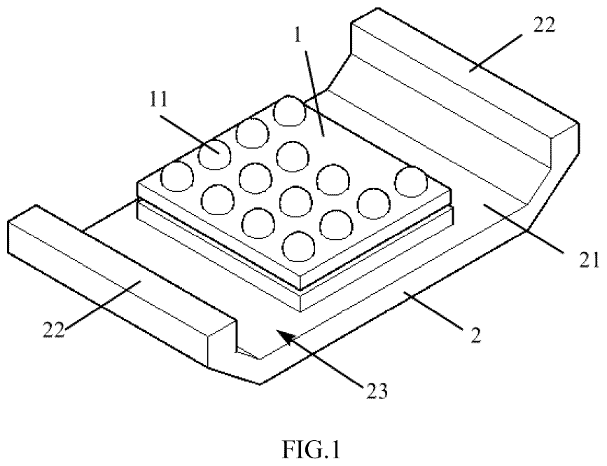

FIG. 1 shows a semiconductor device provided in the embodiment of the application, which comprises a semiconductor chip 1 and a shunt resistor structure 2. Wherein the semiconductor chip 1 comprises a plurality of conductive terminals 11; the shunt resistor structure 2 comprises a main part 21 and a connecting part 22, the connecting part 22 is connected to the end of the main part 21 to form an accommodating space 23, the semiconductor chip 1 is located in the accommodating space 23.

The semiconductor device provided in the embodiment of the application adjusts the positional relationship between the semiconductor chip 1 and the shunt resistor structure 2, so that the semiconductor chip 1 and the shunt resistor structure 2 are no longer parallel and tiled, but rather the semiconductor chip 1 is accommodated within the accommodating space 23 of the shunt resistor structure 2. This reduces the area of the semiconductor device.

In an embodiment, the semiconductor chip 1 is connected to the main part 21, the plurality of conductive terminals 11 of the semiconductor chip 1 comprise a plurality of solder balls; the plurality of solder balls are arranged on one side of the semiconductor chip 1 away from the main part 21. For example, the plurality of solder balls can be arranged on one side of the semiconductor chip 1 away from the main part 21 according to predetermined rules.

In this embodiment, the semiconductor chip 1 comprises a CSP chip made using the CSP process, wherein CSP (Chip Scale Package) process is a chip-level packaging process. In this embodiment, the junction between the main part 21 and the connecting part 22 is flat, resulting in the semiconductor chip 1 being U-shaped as a whole. In other embodiments, the junction between the main part 21 and the connecting part 22 of the shunt resistor is curved or chamfered, resulting in the semiconductor chip 1 being C-shaped as a whole.

In this embodiment, the semiconductor chip 1 is placed within the shunt resistor structure 2. The semiconductor chip 1 is fixed to the shunt resistor structure 2 through an adhesive layer 6, resulting in the formation of a usable semiconductor device. The semiconductor device is connected with external components throuth solder balls and one end of the connecting part 22 of the shunt resistor structure 2 away from the main part 21. This enables the shunt resistor structure 2 to divert the current from the semiconductor chip 1.

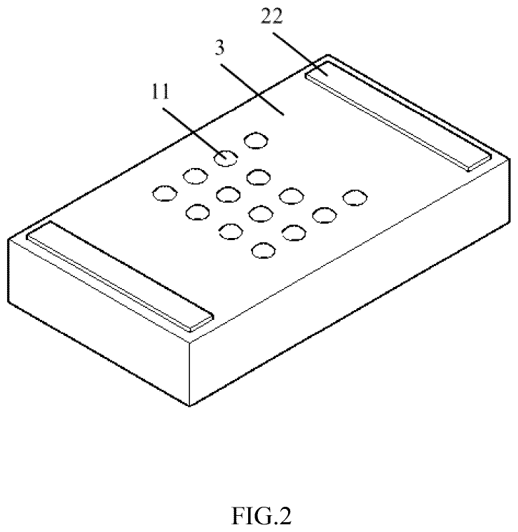

In an embodiment, both one end of the plurality of solder balls being away from the main part 21 and one end of the connecting part 22 being away from the main part 21 are exposed in the main part 21. In an example, one end of the plurality of solder balls being away from the main part 21 aligns with one end of the connecting part 22 being away from the main part 21. The shunt resistor structure 2 and semiconductor chip 1 set in this way can facilitate the connection between the shunt resistor structure 2 and semiconductor chip 1 with external components. In an embodiment, as shown in FIG. 2, the semiconductor device further comprises a first plastic package 3, the first plastic package 3 partially covers the shunt resistor structure 2 and the semiconductor chip 1; wherein, the first plastic package 3 is exposed at one end of the plurality of solder balls away from the main part 21, and the first plastic package 3 is exposed at one end of the connecting part 22 away from the main part 21.

In this embodiment, by packaging the semiconductor chip 1 and shunt resistor structure 2 with the first plastic package 3, it is possible to increase the sealing of the semiconductor chip 1 and shunt resistor structure 2, form protection for the semiconductor chip 1 and shunt resistor structure 2, and standardize the shape of the semiconductor device for ease of installation and use. Furthermore, it does not affect the connection between the semiconductor device and external components that exposing the first plastic package 3 at one end of the plurality of solder balls away from the main part 21, and exposing the first plastic package 3 at one end of the connecting part 22 away from the main part 21.

In an embodiment, the first plastic package 3 is exposed at one side of the main part 21 away from the semiconductor chip 1.

In this embodiment, by exposing the first plastic package 3 at one side of the main part 21 away from the semiconductor chip 1, the heat dissipation performance of the semiconductor device can be increased.

In other embodiments, the first plastic package 3 can be not exposed at one side of the main part 21 away from the semiconductor chip 1. Not exposing the first plastic package 3 can increase the sealing integrity of the semiconductor device.

### Embodiment Two

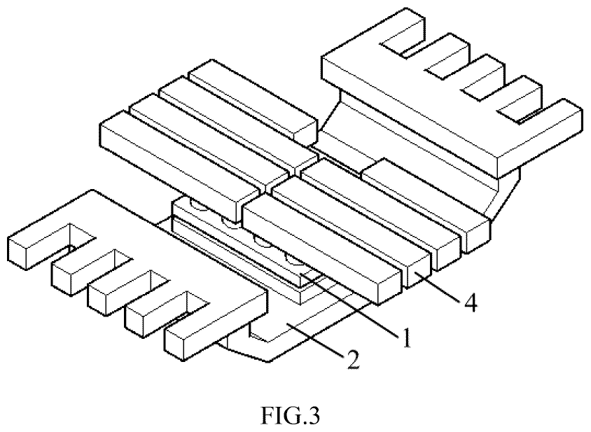

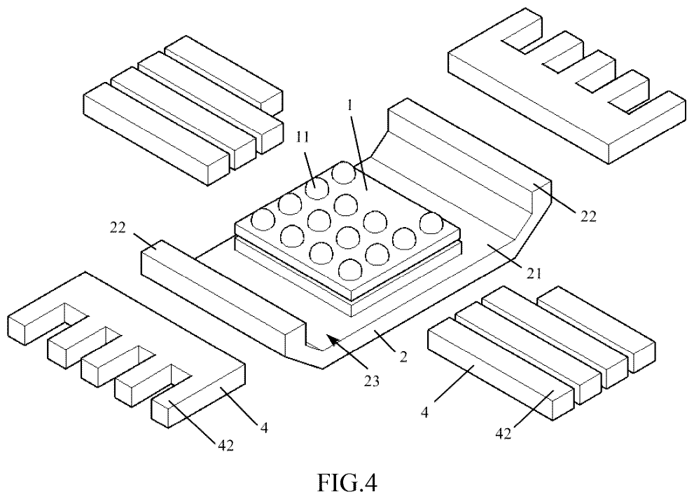

Referred to FIG. 3 and FIG. 4, a semiconductor device provided in the embodiment of the application comprises a semiconductor chip 1 and a shunt resistor structure 2. Wherein the semiconductor chip I comprises a plurality of conductive terminals 11; the shunt resistor structure 2 comprises a main part 21 and a connecting part 22, the connecting part 22 is connected to the end of the main part 21 to form an accommodating space 23, the semiconductor chip 1 is located in the accommodating space 23.

The semiconductor device provided in the embodiment of the application adjusts the positional relationship between the semiconductor chip 1 and the shunt resistor structure 2, so that the semiconductor chip 1 and the shunt resistor structure 2 are no longer parallel and tiled, but rather the semiconductor chip 1 is accommodated within the accommodating space 23 of the shunt resistor structure 2. This reduces the area of the semiconductor device.

In this embodiment, the semiconductor chip 1 comprises a CSP chip made using the CSP process. The plurality of conductive terminals 11 comprise a plurality of solder balls, the plurality of solder balls are arranged on one side of the semiconductor chip I away from the main part 21. The semiconductor device further comprises a lead frame 4, the lead frame 4 has a first surface 41 and a plurality of lead terminals 42, the first surface 41 is configured to connect and carry the semiconductor chip 1 and the shunt resistor structure 2; wherein, each conductive terminal 11 of the semiconductor chip 1 is electrically connected to the corresponding lead terminal 42, the connecting part 22 of the shunt resistor structure 2 is electrically connected to the corresponding lead terminal 42.

In some embodiments, the semiconductor chip 1 is connected in parallel with the shunt resistor structure 2.

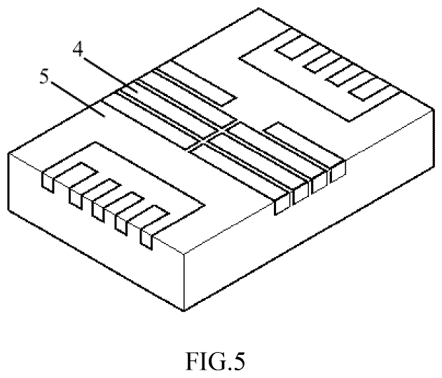

In this embodiment, the semiconductor chip 1 and the shunt resistor structure 2 are both set on the lead frame 4. The semiconductor chip 1 and the shunt resistor structure 2 are connected to external components through the lead frame 4, and the semiconductor chip I is connected in parallel with the shunt resistor structure 2. This enables the shunt resistor structure 2 to divert the current from the semiconductor chip 1. In an embodiment, referred to FIG. 5, the semiconductor device further comprises a second plastic package 5, the second plastic package 5 partially covers the lead frame 4, the semiconductor chip 1, and the shunt resistor structure 2, and the second plastic package 5 is exposed at one side of the lead frame 4 away from the semiconductor chip 1.

In this embodiment, by packaging the semiconductor chip 1 and shunt resistor structure 2 with the second plastic package 5, it is possible to increase the sealing of the semiconductor chip 1 and shunt resistor structure 2, form protection for the semiconductor chip 1 and shunt resistor structure 2, and standardize the shape of the semiconductor device for ease of installation and use. And the shunt resistor structure 2 and the semiconductor chip 1 are connected to external components only through the lead frame 4.

In an embodiment, the second plastic package 5 is exposed at one side of the main part 21 away from the semiconductor chip 1. In this embodiment, by exposing the second plastic package 5 at one side of the main part 21 away from the semiconductor chip 1, the heat dissipation performance of the semiconductor device can be increased.

In other embodiments, the second plastic package 5 can be not exposed at one side of the main part 21 away from the semiconductor chip 1. Not exposing the second plastic package 5 can increase the sealing integrity of the semiconductor device.

### Embodiment Three

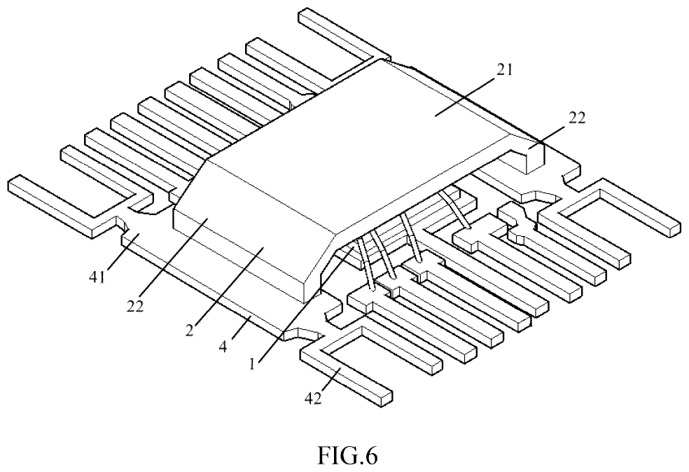

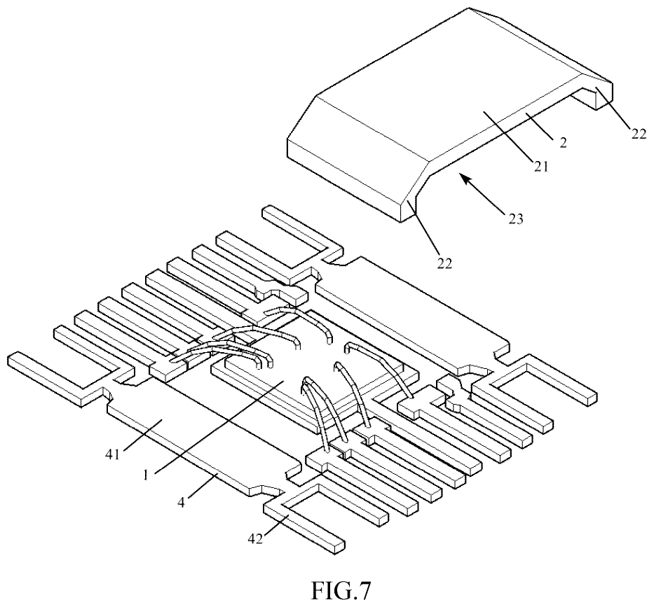

Referred to FIG. 6 and FIG. 7, a semiconductor device provided in the embodiment of the application comprises a semiconductor chip 1 and a shunt resistor structure 2. Wherein the semiconductor chip 1 comprises a plurality of conductive terminals 11; the shunt resistor structure 2 comprises a main part 21 and a connecting part 22, the connecting part 22 is connected to the end of the main part 21 to form an accommodating space 23, the semiconductor chip 1 is located in the accommodating space 23.

The semiconductor device provided in the embodiment of the application adjusts the positional relationship between the semiconductor chip 1 and the shunt resistor structure 2, so that the semiconductor chip 1 and the shunt resistor structure 2 are no longer parallel and tiled, but rather the semiconductor chip 1 is accommodated within the accommodating space 23 of the shunt resistor structure 2. This reduces the area of the semiconductor device.

In this embodiment, the plurality of conductive terminals 11 comprise a plurality of solder pads, the plurality of solder pads are arranged on one side of the semiconductor chip 1 away from the main part 21. And the semiconductor device further comprises wire bonding that electrically connects the semiconductor chip 1 to the corresponding lead terminal 42. In this embodiment, the solder pads can be SMT (Surface Mounted Technology) paster.

The semiconductor device further comprises a lead frame (4), the lead frame (4) has a first surface (41) and a plurality of lead terminals (42), the first surface (41) is configured to connect and carry the semiconductor chip (1) and the shunt resistor structure (2); wherein, each conductive terminal (11) of the semiconductor chip (1) is electrically connected to the corresponding lead terminal (42), the connecting part (22) of the shunt resistor structure (2) is electrically connected to the corresponding lead terminal (42). Wherein the semiconductor chip I is connected in parallel with the shunt resistor structure 2. There is a gap between the semiconductor chip 1 and the main part 21, which is greater than or equal to 0.2 mm.

In this embodiment, the semiconductor chip 1 and the shunt resistor structure 2 are both set on the lead frame 4. The semiconductor chip 1 and the shunt resistor structure 2 are connected to external components through the lead frame 4, and the semiconductor chip 1 is connected in parallel with the shunt resistor structure 2. This enables the shunt resistor structure 2 to divert the current from the semiconductor chip 1.

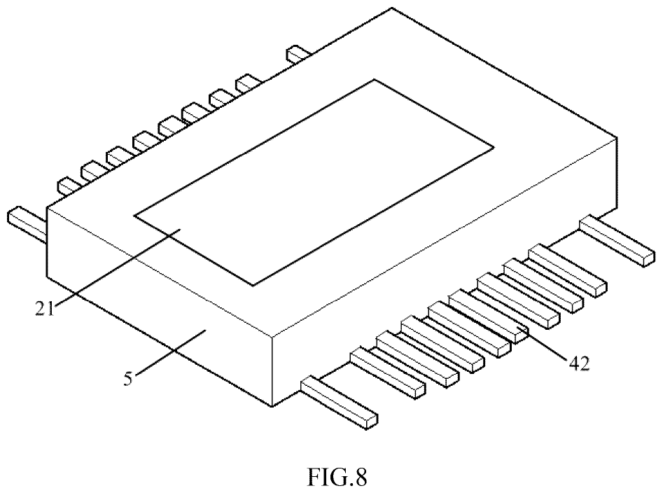

In an embodiment, referred to FIG. 8, the semiconductor device further comprises a second plastic package 5, the second plastic package 5 partially covers the lead frame 4, the semiconductor chip 1, and the shunt resistor structure 2, and the second plastic package 5 is exposed at one side of the lead frame 4 away from the semiconductor chip 1.

In this embodiment, by packaging the semiconductor chip 1 and shunt resistor structure 2 with the second plastic package 5, it is possible to increase the sealing of the semiconductor chip 1 and shunt resistor structure 2, form protection for the semiconductor chip 1 and shunt resistor structure 2, and standardize the shape of the semiconductor device for ease of installation and use. And the shunt resistor structure 2 and the semiconductor chip 1 are connected to external components only through the lead frame 4.

In an embodiment, the second plastic package 5 is exposed at one side of the main part 21 away from the semiconductor chip 1.

In this embodiment, by exposing the second plastic package 5 at one side of the main part 21 away from the semiconductor chip 1, the heat dissipation performance of the semiconductor device can be increased.

In other embodiments, the second plastic package 5 can be not exposed at one side of the main part 21 away from the semiconductor chip 1. Not exposing the second plastic package 5 can increase the sealing integrity of the semiconductor device.

In the above embodiments, refer to FIG. 1, FIG. 4, or FIG. 6, where there are two connecting parts 22 and one main part 21. The two connection parts 22 are located at the opposite ends of the main part 21, and there is an angle between the connection parts 22 and the main part 21, forming a accommodating space 23. Wherein the end of the connecting part 22 being away from the main part 21 is directly or indirectly connected to external components. In an example, the connection parts 22 are directly connected to the external PCB board, or the connection parts 22 are connected to the lead frame 4, thus achieving an indirect connection with the external PCB board.

In an embodiment, the connection part 22 and the main part 21 of the mentioned shunt resistor structure 2 above are integrally formed and made of manganese copper material. In this embodiment, the connecting part 22 and the main part 21 are both part of the shunt resistor and form a shunt resistor for diverting the current from the semiconductor chip 1. In other embodiments, only the main part 21 serves as the shunt resistor for diverting the current from the semiconductor chip 1, while the function of the connecting part 22 is to electrically connect the main part 21 with the external components/lead frame 4.

In the above embodiments, each description has its own emphasis. For parts that are not detailed in one embodiment, please refer to the relevant descriptions of other embodiments.

In summary, although the present application has been disclosed with preferred embodiments as described above, the aforementioned preferred embodiments are not intended to limit the scope of the application. Ordinary skilled in the art can make various modifications and improvements within the spirit and scope of the present application. Therefore, the protection scope of the application should be determined by the boundaries defined in the claims.

1. A semiconductor device, comprising:
a semiconductor chip (1), the semiconductor chip (1) comprises a plurality of conductive terminals (11);
a shunt resistor structure (2), the shunt resistor structure (2) comprises a main part (21) and a connecting part (22), the connecting part (22) is connected to the end of the main part (21) to form an accommodating space (23), the semiconductor chip (1) is located in the accommodating space (23).

2. The semiconductor device according to claim 1, wherein the semiconductor chip (1) is connected to the main part (21), the plurality of conductive terminals (11) of the semiconductor chip (1) comprise a plurality of solder balls;
the plurality of solder balls are arranged on one side of the semiconductor chip (1) away from the main part (21).

3. The semiconductor device according to claim 2, wherein one end of the plurality of solder balls being away from the main part (21) aligns with one end of the connecting part (22) being away from the main part (21).

4. The semiconductor device according to claim 2, wherein the semiconductor device further comprises a first plastic package (3), the first plastic package (3) partially covers the shunt resistor structure (2) and the semiconductor chip (1);
wherein, the first plastic package (3) is exposed at one end of the plurality of solder balls away from the main part (21), and the first plastic package (3) is exposed at one end of the connecting part (22) away from the main part (21).

5. The semiconductor device according to claim 4, wherein the first plastic package (3) is exposed at one side of the main part (21) away from the semiconductor chip (1).

6. The semiconductor device according to claim 4, wherein the first plastic package (3) isn't exposed at one side of the main part (21) away from the semiconductor chip (1).

7. The semiconductor device according to claim 1, wherein the semiconductor device further comprises:
a lead frame (4), the lead frame (4) has a first surface (41) and a plurality of lead terminals (42), the first surface (41) is configured to connect and carry the semiconductor chip (1) and the shunt resistor structure (2);
wherein, each conductive terminal (11) of the semiconductor chip (1) is electrically connected to the corresponding lead terminal (42), the connecting part (22) of the shunt resistor structure (2) is electrically connected to the corresponding lead terminal (42).

8. The semiconductor device according to claim 7, wherein the plurality of conductive terminals (11) comprise a plurality of solder balls, the plurality of solder balls are arranged on one side of the semiconductor chip (1) away from the main part (21).

9. The semiconductor device according to claim 7, wherein the plurality of conductive terminals (11) comprise a plurality of solder pads, the plurality of solder pads are arranged on one side of the semiconductor chip (1) away from the main part (21).

10. The semiconductor device according to claim 9, wherein the semiconductor device further comprises a wire bonding which electrically connects the semiconductor chip (1) to the corresponding lead terminal (42).

11. The semiconductor device according to claim 7, wherein the semiconductor device further comprises:
a second plastic package (5), the second plastic package (5) partially covers the lead frame (4), the semiconductor chip (1), and the shunt resistor structure (2).

12. The semiconductor device according to claim 11, wherein the second plastic package (5) is exposed at one side of the lead frame (4) away from the semiconductor chip (1).

13. The semiconductor device according to claim 11, wherein the second plastic package (5) is exposed at one side of the main part (21) away from the semiconductor chip (1).

14. The semiconductor device according to claim 11, wherein the second plastic package (5) isn't exposed at one side of the main part (21) away from the semiconductor chip (1).

15. The semiconductor device according to claim 1, wherein the semiconductor chip (1) comprises a CSP chip.
